(19) United States
(12) Patent Application Publication
(10) Pub. No.: US 2014/0008117 A1
(43) Pub. Date: Jan. 9, 2014

(54) CONNECTING STRUCTURE OF CIRCUIT BOARD

(71) Applicant: Hsin-Mao Huang, Changhua County (TW)

(72) Inventor: Hsin-Mao Huang, Changhua County (TW)

(73) Assignee: NANYA TECHNOLOGY CORPORATION, Taoyuan (TW)

(21) Appl. No.: 13/541,649

(22) Filed: Jul. 3, 2012

(51) Int. Cl. H05K 1/11

(52) U.S. Cl. 174/261

(57) ABSTRACT

A connecting structure of a circuit board is provided. The connecting structure includes at least one connecting trace and at least one connecting pad. The connecting trace and the connecting pad are disposed on a surface, or inside of the circuit board. The connecting pad has a first end surface and a second end surface at two opposite end surfaces thereof. The first end surface is a convex curved surface and connected to the connecting trace, and a cross section area of the connecting pad is gradually increased from the first end surface.

### BACKGROUND OF THE INVENTION

1. Field of the Invention

The present invention generally relates to a connecting structure. More particularly, the present invention relates to a connecting structure of a circuit board.

2. Description of Related Art

On or inside of the printed circuit board and packaging substrate, the connecting traces used for the electrical connections between two terminals are generally kept a consistent cross section area or an approximate cross section area, so that the characteristic impedance of the connecting traces can remain the same. Especially for the signal transmission of high speed and high frequency signals, a better impedance match between two terminals is further required for the circuit designers because the un-matched impedance between the terminals will cause the signal reflection and reduce the quality of signal transmission.

The conventional signal transmission structure at least includes a connecting pad and a connecting trace. The connecting trace is connected with the connecting pad, and the connecting pads are suitable for connecting with the electrodes of the electronic component to transmit signals.

However, in the conventional signal transmission structure, the characteristic impedance value of the connecting pad is different from the characteristic impedance value of the connecting trace. Moreover, the difference between the cross section area of the connecting pad and the connecting trace is considerably great, which deteriorates the impedance consistency between the connecting pad and the connecting trace. In other words, the impedance consistency between the connecting pads and the connecting traces is not satisfactory, which causes increased insertion loss in signal transmission, thus adversely affecting the signal transmission quality.

### SUMMARY OF THE INVENTION

Accordingly, the present invention is directed to a connecting structure of a circuit board which improves the impedance consistency between the connecting pads and the connecting traces thereof.

The present invention provides a connecting structure of a circuit board. The connecting structure includes at least one connecting trace and at least one connecting pad. The at least one connecting trace is disposed on a surface, or inside of the circuit board. The at least one connecting pad is disposed on the surface, or inside of the circuit board. The at least one connecting pad has a first end surface and a second end surface at two opposite end surfaces thereof. The first end surface is a convex curved surface and connected to the connecting trace, and a cross section area of the connecting pad is gradually increased from the first end surface.

The present invention provides a connecting structure of a circuit board. The connecting structure comprises at least one connecting trace and at least one connecting pad. The connecting trace is disposed on a surface, or inside of the circuit board. The connecting pad is disposed on the surface, or inside of the circuit board. The at least one connecting pad has a first end surface and a second end surface at two opposite end surfaces thereof, wherein the first end surface is a planar surface and connected to the connecting trace, and a cross section area of the first end surface is substantially equal to a cross section area of the connecting trace.

According to an embodiment of the present invention, the cross section area of the connecting pad is gradually increased from the first end surface toward the second end surface, and a cross section area of the first end surface is smaller than that of the second end surface.

According to an embodiment of the present invention, the second end surface of the connecting pad is a planar surface.

According to an embodiment of the present invention, the connecting pad has a curved profile from the first end surface to the second end surface.

According to an embodiment of the present invention, the cross section area of the connecting pad is first gradually increased and then decreased from the first end surface toward the second end surface, and a cross section area of the first end surface is equal to that of the second end surface.

According to an embodiment of the present invention, the second end surface of the connecting pad is a convex curved surface.

According to an embodiment of the present invention, the connecting pad has a curved profile.

According to an embodiment of the present invention, the at least one connecting trace is two connecting traces, the at least one connecting pad is two connecting pads, the two connecting traces and the two connecting pads are extending along a direction, the two connecting pads are disposed adjacent to each other and there is a distance between the two connecting pads, at least one electronic component has a first electrode and a second electrode at two opposite ends thereof respectively, and the first electrode and the second electrode are respectively connected to the two connecting pads.

According to an embodiment of the present invention, the orthogonal projections of the first electrode and the second electrode of the electronic component on the circuit board are overlapped with the two connecting pads on the circuit board.

According to an embodiment of the present invention, a shape of the first electrode and a shape of the second electrode are respectively conformal to two shapes of the two corresponding pads.

According to an embodiment of the present invention, the electronic component is an active device, or a passive device.

According to an embodiment of the present invention, the second end surface is a planar surface and the cross section area of the second end surface is substantially equal to the cross section area of the first end surface.

According to an embodiment of the present invention, the second end surface is a planar end surface and the cross section area of the second end surface is greater than the cross section area of the first end surface.

According to an embodiment of the present invention, the second end surface is a planar surface.

According to an embodiment of the present invention, a cross section area of the connecting pad is gradually increased from the first end surface toward the second end surface, and a cross section area of the second end surface is greater than the cross section area of the first end surface.

According to an embodiment of the present invention, the connecting pad has a hopper profile.

Based on the above description, the cross section area of the first end surface of the connectingg pad is similar to the cross section area of the connecting trace, so as to avoid the sudden change of the cross section areas from the connecting trace to the connecting pad in the conventional design. Therefore, the impedance consistency between the connecting pad and the connecting trace can be improved, and the signal transmission quality of the connecting structures and the electronic component disposed thereon is also improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic partial top view of a connecting structure of a circuit board according to an embodiment of the invention.

FIG. 2 is a schematic partial top view of a connecting structure of a circuit board according to another embodiment of the invention.

FIG. 3 is a schematic partial top view of a connecting structure of a circuit board according to another embodiment of the invention.

FIG. 4 is a schematic partial top view of a connecting structure of a circuit board according to another embodiment of the invention.

FIG. 5 is a schematic partial top view of a connecting structure and an electronic component according to an embodiment of the invention.

FIG. 6 is a schematic partial top view of a connecting structure and an electronic component according to another embodiment of the invention.

FIG. 7 is a schematic partial top view of a connecting structure and an electronic component according to another embodiment of the invention.

### DESCRIPTION OF THE EMBODIMENTS

Reference will now be made in detail to the present preferred embodiments of the invention, examples of which are illustrated in the accompanying drawings.

Wherever possible, the same reference numbers are used in the drawings and the description to refer to the same or like parts.

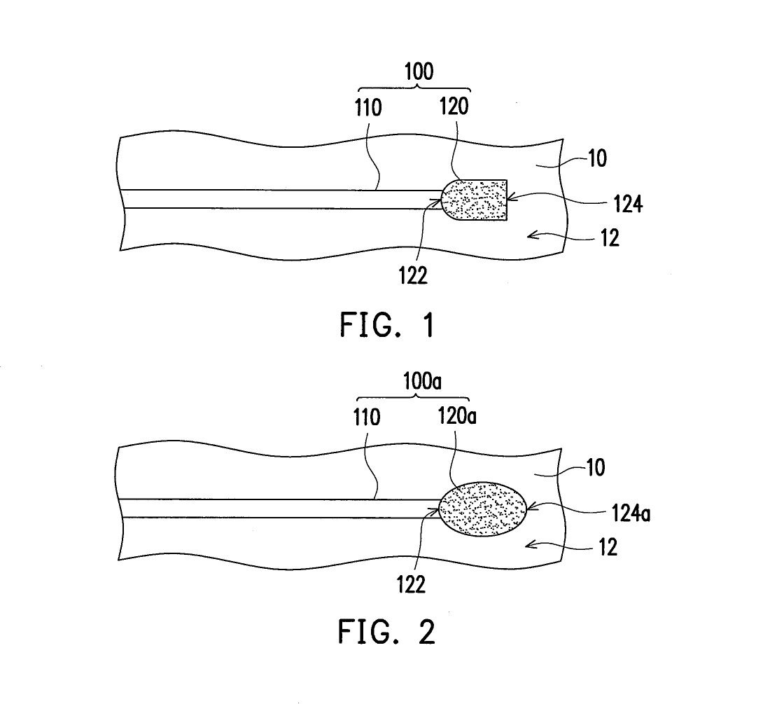

FIG. 1 is a schematic partial top view of a connecting structure of a circuit board according to an embodiment of the invention. Referring to FIG. 1, in the present embodiment, the connecting structure 100 of a circuit board 10 includes at least one connecting trace 110 (one connecting trace 110 is illustrated herein) and at least one connecting pad 120 (one connecting pad 120 is illustrated herein). The connecting trace 110 is disposed on a surface 12 of the circuit board 10, and the connecting pad 120 is also disposed on the surface 12 of the circuit board 10. The at least one connecting pad 120 has a first end surface 122 and a second end surface 124 which are at two opposite end surfaces of the connecting pad 120. The first end surface 122 is a convex curved surface and connected to the connecting trace 110, and the second end surface 124 of the connecting pad 120, in the present embodiment, is a planar surface. The cross section area of the connecting pad 120 is gradually increased from the first end surface 122 toward the second end surface 124. In the present embodiment, the cross section area of the first end surface 122 is smaller than the cross section area of the second end surface 124, and the cross section area of the first end surface 122 of the connecting pad 120 is similar to the cross section are of the connecting trace 110.

With the design of the connecting structure 100 described above, the cross section area of the first end surface 122 of the connecting pad 120 is similar to the cross section area of the connecting trace 110, and then the cross section area of the connecting pad 120 is gradually increased from the first end surface 122, so as to avoid the sudden change of the cross section area from the connecting trace to the connecting pad in the conventional design. Therefore, the impedance consistency between the connecting pad 120 and the connecting trace 110 can be improved, and the signal transmission quality of the connecting structure 100 may be further improved.

It should be noted the component notations and partial details of the structures hereinafter provided in the below embodiments can be the same as or similar to the previous embodiment, wherein the same notations represent the same or similar components while the repeated same details are omitted, which can refer to the previous embodiment.

FIG. 2 is a schematic partial top view of a connecting structure of a circuit board according to another embodiment of the invention. Referring to FIG. 2, a connecting structure 100a of the present embodiment is similar to the connecting structure 100 of the previous embodiment, and the connecting structure 100a is capable of achieving similar effects as the connecting structure 100. The difference is further illustrated hereafter, with the similar parts thereof omitted from further description.

In the present embodiment, the second end surface 124a of the connecting pad 120a is a convex curved surface, and the connecting pad 120a has a curved profile.

Herein, the cross section area of the connecting pad 120a is first gradually increased and then decreased from the first end surface 122 toward the second end surface 124a. The cross section area of the first end surface 122 is equal to the cross section area of the second end surface 124a. In other words, the shape of the connecting pad 120a is symmetrical, and in the present embodiment, the connecting pad 120a is in ellipse shape, but the invention is not limited thereto.

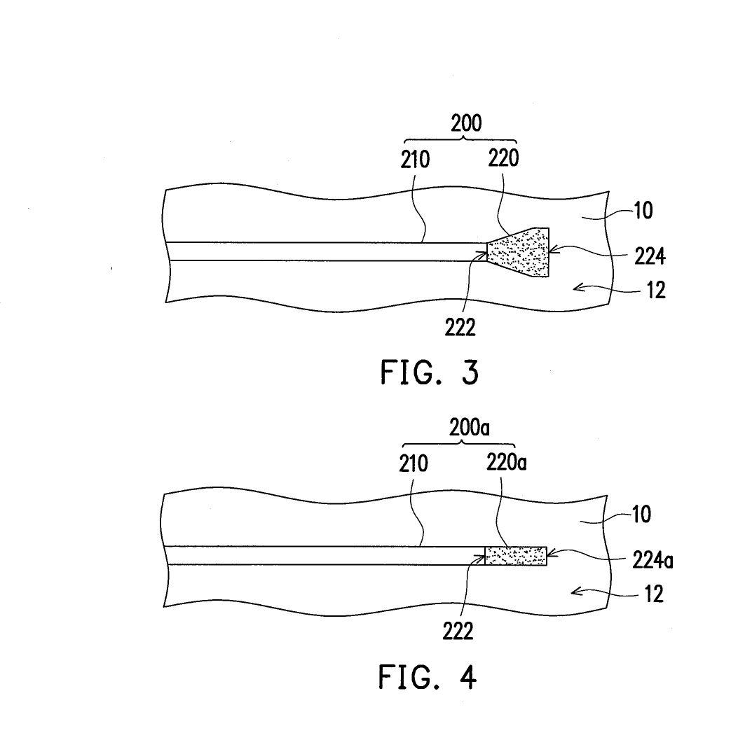

FIG. 3 is a schematic partial top view of a connecting structure of a circuit board according to another embodiment of the invention. Referring to FIG. 3, a connecting structure 200 of the present embodiment is similar to the connecting structure 100 of the previous embodiment, and the connecting structure 200 is capable of achieving similar effects as the connecting structure 100. The difference is further illustrated hereafter, with the similar parts thereof omitted from further description.

Referring to FIG. 3, in the present embodiment, the first end surface 222 of the connecting pad 220 is a planar surface and is connected to the connecting trace 210, and the cross section area of the first end surface 222 is substantially equal to the cross section area of the connecting trace 210. In the present embodiment, a cross section area of the connecting pad 220 is gradually increased from the first end surface 222 toward the second end surface 224, and the cross section area of the second end surface 224 is greater than the cross section area of the first end surface 222. The second end surface 224 of the present embodiment is a planar surface, and the connecting pad 220 has a hopper profile, but the invention is not limited thereto.

FIG. 4 is a schematic partial top view of a connecting structure of a circuit board according to another embodiment of the invention. Referring to FIG. 4, a connecting structure 200a of the present embodiment is similar to the connecting structure 200 of the previous embodiment, and the connecting structure 200a is capable of achieving similar effects as the connecting structure 200. The difference is further illustrated hereafter, with the similar parts thereof omitted from further description.

Referring to FIG. 4, in the present embodiment, the second end surface 224a is a planar surface and the cross section area of the second end surface 224a is substantially equal to the cross section area of the first end surface 222. In other words, the profile of the connecting pad 200a is the straight-light extending profile of the connecting trace 210. Therefore, there is no sudden change of the cross section areas from the connecting trace 210 to the connecting pad 220a, the impedance consistency of the connecting structure 200a is thus enhanced.

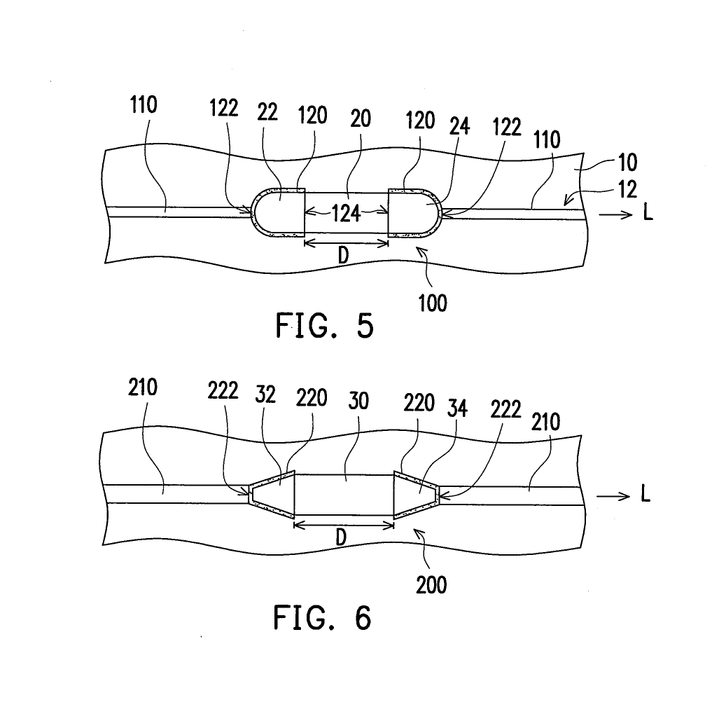

FIG. 5 is a schematic partial top view of a connecting structure and an electronic component according to an embodiment of the invention. Referring to FIG. 5, for mounting at least one electronic component 20 (one electronic 20 is illustrated herein) on the circuit board 10, the connecting structures 100 including two connecting pads 120 and two connecting traces 110 are disposed in pair on the circuit board. The connecting structure 100′ of the present embodiment is substantially the same with the connecting structure 100 in FIG. 1. In the present embodiment, the two connecting traces 110 and the two connecting pads 120 are extending along a direction L, and the two connecting pads 120 are disposed adjacent to each other and there is a distance D between the two connecting pads 120. The electronic component 20 may be, for example, an active device or a passive device, for example, a semiconductor device, an integrated circuit chip, a photoelectric element, a micro mechanical-electrical device, a capacitor, an inductor, a resistor, or the like.

The electronic component 20 has a first electrode 22 and a second electrode 24 located respectively at two opposite ends of the electronic component 20. The first electrode 22 and the second electrode 24 are respectively disposed on and electronically connected to the two connecting pads 120. Moreover, the orthogonal projections of the first electrode 22 and the second electrode 24 of the electronic component 20 on the circuit board are overlapped with the two connecting pads 120 on the circuit board. More specifically, each of the electrodes 22 and 24 has a bottom surface, and the shapes of bottom surfaces of the first electrode 22 and the second electrode 24 are respectively conformal to two shapes of the two connecting pads 120. Since the shapes of bottom surface of the first electrode 22 and the second electrode 24 are respectively conformal to the shapes of the two connecting pads 120, the signal transmission quality of the connecting structures 100 and the electronic component 20 disposed thereon is improved, and the structure stability of the connecting structures 100 is also enhanced.

FIG. 6 is a schematic partial top view of a connecting structure and an electronic component according to another embodiment of the invention. Referring to FIG. 3, the connecting structure 200 of the present embodiment is substantially the same with the connecting structure 200 in FIG. 3. Also, the connecting structure 200 and the electronic component 30 are capable of achieving similar effects as the connecting structure 100 and the electronic component 20 in FIG. 5. The difference is further illustrated hereafter, with the similar parts thereof omitted from further description.

The orthogonal projections of the first electrode 32 and the second electrode 34 of the electronic component 30 on the circuit board are overlapped with the two connecting pads 220 on the circuit board. More specifically, each of the electrodes 32 and 34 has a bottom surface, and the shapes of bottom surfaces of the first electrode 32 and the second electrode 34 are respectively conformal to the shapes of the two connecting pads 220 so that the signal transmission quality of the connecting structures 200 and the electronic component 30 disposed thereon is improved.

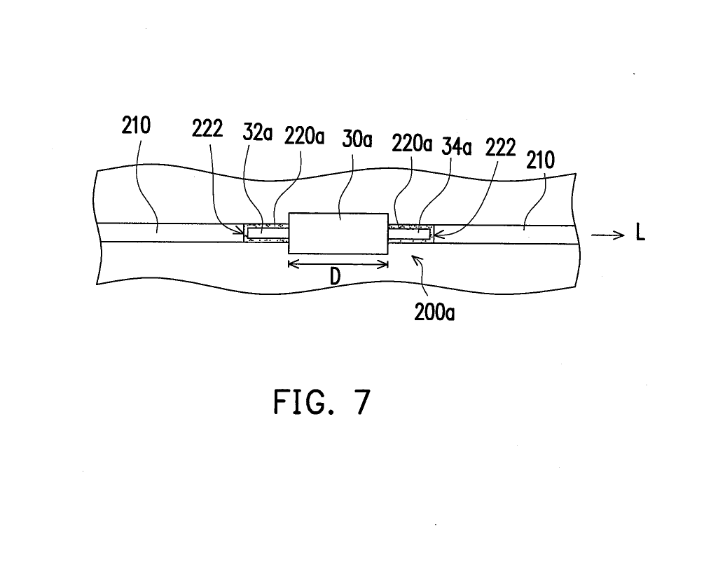

FIG. 7 is a schematic partial top view of a connecting structure and an electronic component according to another embodiment of the invention. Referring to FIG. 4, the connecting structure 200a of the present embodiment is substantially the same with the connecting structure 200a in FIG. 4. Also, the connecting structure 200a and the electronic component 30a are capable of achieving similar effects as the connecting structure 100 and the electronic component 20 in FIG. 5. The difference is further illustrated hereafter, with the similar parts thereof omitted from further description.

The orthogonal projections of the first electrode 32a and the second electrode 34a of the electronic component 30a on the circuit board are overlapped with the two connecting pads 220a on the circuit board. More specifically, each of the electrodes 32a and 34a has a bottom surface, and the shapes of bottom surfaces of the first electrode 32a and the second electrode 34a are respectively conformal to the shapes of the two connecting pads 220a so that the signal transmission quality of the connecting structures 200a and the electronic component 30a disposed thereon is improved.

In summary, in the embodiments of the invention described above, the cross section area of the first end surface of the connecting pad is similar to the cross section area of the connecting trace, and then the cross section area of the connecting pad is gradually increased from the first end surface or equal to the cross section area of the connecting trace, so as to avoid the sudden change of the cross section areas from the connecting trace to the connecting pad in the conventional design. Therefore, the impedance consistency between the connecting pad and the connecting trace can be improved, and the signal transmission quality of the connecting structures and the electronic component disposed thereon is also improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A connecting structure of a circuit board, comprising:
at least one connecting trace, disposed on a surface, or inside of the circuit board; and
at least one connecting pad, disposed on the surface, or inside of the circuit board, the at least one connecting pad having a first end surface and a second end surface at two opposite end surfaces thereof, wherein the first end surface is a convex curved surface and connected to the connecting trace, and a cross section area of the connecting pad is gradually increased from the first end surface.

2. The connecting structure of the circuit board as recited in claim 1, wherein the cross section area of the connecting pad is gradually increased from the first end surface toward the second end surface, and a cross section area of the first end surface is smaller than that of the second end surface.

3. The connecting structure of the circuit board as recited in claim 2, wherein the second end surface of the connecting pad is a planar surface.

4. The connecting structure of the circuit board as recited in claim 1, wherein the cross section area of the connecting pad is first gradually increased and then decreased from the first end surface toward the second end surface, and a cross section area of the first end surface is equal to that of the second end surface.

5. The connecting structure of the circuit board as recited in claim 4, wherein the second end surface of the connecting pad is a convex curved surface.

6. The connecting structure of the circuit board as recited in claim 4, wherein the connecting pad has a curved profile.

7. The connecting structure of the circuit board as recited in claim 1, wherein the at least one connecting trace is two connecting traces, the at least one connecting pad is two connecting pads, the two connecting traces and the two connecting pads are extending along a direction, the two connecting pads are disposed adjacent to each other and there is a distance between the two connecting pads, at least one electronic component has a first electrode and a second electrode at two opposite ends thereof respectively, and the first electrode and the second electrode are respectively connected to the two connecting pads.

8. The connecting structure of the circuit board as recited in claim 7, wherein the orthogonal projections of the first electrode and the second electrode of the electronic component on the circuit board are overlapped with the two connecting pads on the circuit board.

9. The connecting structure of the circuit board as recited in claim 7, wherein a shape of the first electrode and a shape of the second electrode are respectively conformal to two shapes of the two corresponding pads.

10. The connecting structure of the circuit board as recited in claim 7, wherein the electronic component is an active device, or a passive device.

11. A connecting structure of a circuit board, comprising:
at least one connecting trace, disposed on a surface, or inside of the circuit board; and
at least one connecting pad, disposed on the surface, or inside of the circuit board, the at least one connecting pad having a first end surface and a second end surface at two opposite end surfaces thereof, wherein the first end surface is a planar surface and connected to the connecting trace, and a cross section area of the first end surface is substantially equal to a cross section area of the connecting trace.

12. The connecting structure of the circuit board as recited in claim 11, wherein a cross section area of the second end surface is substantially equal to the cross section area of the first end surface.

13. The connecting structure of the circuit board as recited in claim 12, wherein the second end surface is a planar surface.

14. The connecting structure of the circuit board as recited in claim 11, wherein a cross section area of the connecting pad is gradually increased from the first end surface toward the second end surface, and a cross section area of the second end surface is greater than the cross section area of the first end surface.

15. The connecting structure of the circuit board as recited in claim 14, wherein the second end surface is a planar surface.

16. The connecting structure of the circuit board as recited in claim 14, wherein the connecting pad has a hopper profile.

17. The connecting structure of the circuit board as recited in claim 11, wherein the at least one connecting trace is two connecting traces, the at least one connecting pad is two connecting pads, the two connecting traces and the two connecting pads are extending along a direction, the two connecting pads are disposed adjacent to each other and there is a distance between the two connecting pads, at least one electronic component has a first electrode and a second electrode at two opposite ends thereof respectively, the first electrode and the second electrode are respectively connected to the two connecting pads.

18. The connecting structure of the circuit board as recited in claim 17, wherein the orthogonal projections of the first electrode and the second electrode of the electronic component on the circuit board are overlapped with the two connecting pads on the circuit board.

19. The connecting structure of the circuit board as recited in claim 17, wherein a shape of the first electrode and a shape of the second electrode are respectively conformal to two shapes of the two corresponding pads.

20. The connecting structure of the circuit board as recited in claim 17, wherein the electronic component is an active device, or a passive device.
